(19) United States
(12) Patent Application Publication
(10) Pub. No.: US 2026/0011970 A1
(43) Pub. Date: Jan. 8, 2026

(54) LASER CHAMBER, GAS LASER DEVICE, AND ELECTRONIC DEVICE MANUFACTURING METHOD

(71) Applicant: Gigaphoton Inc., Tochigi (JP)

(72) Inventor: Hideaki MINAMI, Tochigi (JP)

(73) Assignee: Gigaphoton Inc., Tochigi (JP)

(21) Appl. No.: 19/226,397

(22) Filed: Jun. 3, 2025

(30) Foreign Application Priority Data
Jul. 4, 2024 (JP) 2024-108369

(51) Int. Cl. H01S 3/041; G03F 7/00; H01S 3/036; H01S 3/04

(52) U.S. Cl. CPC H01S 3/041; G03F 7/70025; G03F 7/70858; H01S 3/036; H01S 3/0407

(57) ABSTRACT

A laser chamber of a gas laser device configured to output laser light includes a container filled with a laser gas, a first electrode extending in a first direction and arranged in the container, a second electrode arranged at a position closer to an inner wall of the container than the first electrode while extending in the first direction and facing the first electrode in a second direction perpendicular to the first direction, a fan configured to cause the laser gas to flow through a discharge space between the first electrode and the second electrode, a plurality of heat pipes arranged on the inner wall of the container, and a plurality of heat exchangers arranged as being spaced apart from each other in the container.

### CROSS-REFERENCE TO RELATED APPLICATIONS

The present application claims the benefit of Japanese Patent Application No. 2024-108369, filed on Jul. 4, 2024, the entire contents of which are hereby incorporated by reference.

### BACKGROUND

### 1. Technical Field

The present disclosure relates to a laser chamber, a gas laser device, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248 nm and an ArF excimer laser device for outputting laser light having a wavelength of about 193 nm are used.

The KrF excimer laser device and the ArF excimer laser device each have a large spectral line width of about 350 to 400 pm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be line-narrowed to the extent that the chromatic aberration can be ignored. For this purpose, there is a case in which a line narrowing module (LNM) including a line narrowing element (etalon, grating, and the like) is provided in a laser resonator of the gas laser device to line-narrow a spectral line width. In the following, a gas laser device with a narrowed spectral line width is referred to as a line narrowing gas laser device.

### LIST OF DOCUMENTS

### Patent Documents

Patent Document 1: Japanese Patent Application Publication No. 2002-151763

### SUMMARY

A laser chamber of a gas laser device, according to an aspect of the present disclosure, configured to output laser light includes a container filled with a laser gas, a first electrode extending in a first direction and arranged in the container, a second electrode arranged at a position closer to an inner wall of the container than the first electrode while extending in the first direction and facing the first electrode in a second direction perpendicular to the first direction, a fan configured to cause the laser gas to flow through a discharge space between the first electrode and the second electrode, a plurality of heat pipes arranged on the inner wall of the container, and a plurality of heat exchangers arranged as being spaced apart from each other in the container.

A gas laser device, according to an aspect of the present disclosure, configured to output laser light includes an optical resonator and a laser chamber arranged to have an optical path of the optical resonator pass therethrough. Here, the laser chamber includes a container filled with a laser gas, a first electrode extending in a first direction and arranged in the container, a second electrode arranged at a position closer to an inner wall of the container than the first electrode while extending in the first direction and facing the first electrode in a second direction perpendicular to the first direction, a fan configured to cause the laser gas to flow through a discharge space between the first electrode and the second electrode, a plurality of heat pipes arranged on the inner wall of the container, and a plurality of heat exchangers arranged as being spaced apart from each other in the container.

An electronic device manufacturing method according to an aspect of the present disclosure includes generating laser light using a gas laser device, outputting the laser light to an exposure apparatus, and exposing a photosensitive substrate to the laser light in the exposure apparatus to manufacture an electronic device. Here, the gas laser device is configured to output the laser light and includes an optical resonator and a laser chamber arranged to have an optical path of the optical resonator pass therethrough. The laser chamber includes a container filled with a laser gas, a first electrode extending in a first direction and arranged in the container, a second electrode arranged at a position closer to an inner wall of the container than the first electrode while extending in the first direction and facing the first electrode in a second direction perpendicular to the first direction, a fan configured to cause the laser gas to flow through a discharge space between the first electrode and the second electrode, a plurality of heat pipes arranged on the inner wall of the container, and a plurality of heat exchangers arranged as being spaced apart from each other in the container.

### BRIEF DESCRIPTION OF THE DRAWINGS

An embodiment of the present disclosure will be described below merely as examples with reference to the accompanying drawings.

FIG. 1 is a side view schematically showing the configuration of a gas laser device according to a comparative example.

FIG. 2 is a sectional view schematically showing the configuration of the gas laser device according to the comparative example.

FIG. 3 is a sectional view showing in detail the configuration of a laser chamber according to an embodiment.

FIG. 4 is a sectional view showing a cross-section of a bottom of a container taken along a YZ plane.

FIG. 5 is a sectional view showing the configuration of a heat exchanger.

FIG. 6 is a diagram showing an example of a connection state of a plurality of heat exchangers.

FIG. 7 is a diagram schematically showing a configuration example of an exposure apparatus.

### DESCRIPTION OF EMBODIMENTS

### <Contents>

1. Comparative example
   1.1 Configuration
   1.2 Operation
   1.3 Problem
2. Embodiment
   2.1 Configuration
   2.2 Operation
   2.3 Effect
3. Electronic device manufacturing method

Hereinafter, an embodiment of the present disclosure will be described in detail with reference to the drawings. The embodiment described below shows some examples of the present disclosure and do not limit the contents of the present disclosure. Also, all configurations and operation described in the embodiment are not necessarily essential as configurations and operation of the present disclosure. Here, the same components are denoted by the same reference numeral, and duplicate description thereof is omitted.

### 1. Comparative Example

First, a comparative example of the present disclosure will be described. The comparative example of the present disclosure is an example recognized by the applicant as known only by the applicant, and is not a publicly known example admitted by the applicant.

### 1.1 Configuration

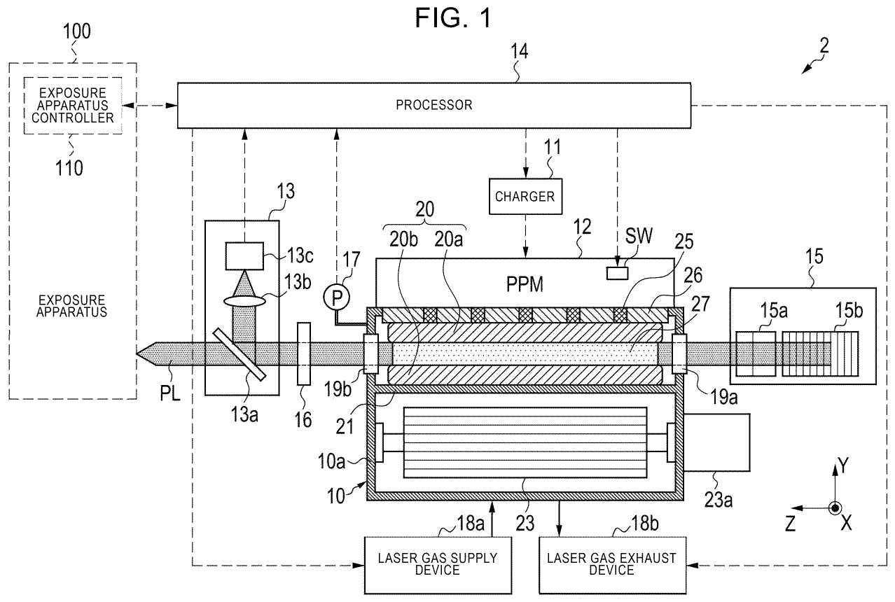

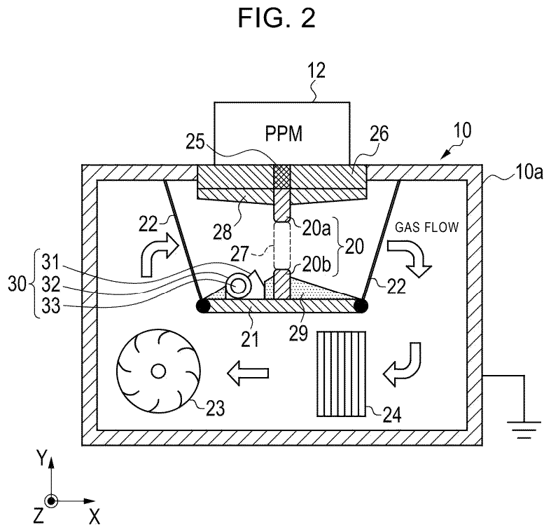

The configuration of a gas laser device 2 according to the comparative example will be described using FIGS. 1 and 2. FIG. 1 schematically shows the configuration of the gas laser device 2. FIG. 2 is a sectional view of the gas laser device 2 shown in FIG. 1 viewed from a Z direction. The gas laser device 2 is a discharge-excitation-type gas laser device that causes discharge and excites a laser gas, and is, for example, an excimer laser device.

In FIG. 1, the travel direction of pulse laser light PL output from the gas laser device 2 is defined as the Z direction. A discharge direction to be described later is defined as a Y direction. A direction orthogonal to the Z direction and the Y direction is defined as an X direction. Here, the pulse laser light PL is an example of the “laser light” according to the technology of the present disclosure. The Z direction is an example of the “first direction” according to the technology of the present disclosure. The Y direction is an example of the “second direction” according to the technology of the present disclosure. The X direction is an example of the “third direction” according to the technology of the present disclosure.

In FIG. 1, the gas laser device 2 is a line narrowing gas laser device including a laser chamber 10, a charger 11, a pulse power module (PPM) 12, a pulse energy measurement unit 13, a processor 14, a pressure sensor 17, and a laser resonator. The laser resonator is configured of a line narrowing module 15 and an output coupling mirror 16.

The laser chamber 10 includes, for example, a container 10a made of aluminum metal plated with nickel on the surface thereof. As shown in FIGS. 1 and 2, a main electrode 20, a ground plate 21, wirings 22, a fan 23, a heat exchanger 24, an insulating guide 28, a conductive guide 29, and a preionization electrode 30 are provided in the container 10a. The preionization electrode 30 includes a preionization outer electrode 31, a dielectric pipe 32, and a preionization inner electrode 33.

A laser gas containing fluorine as a laser medium is enclosed in the container 10a. The laser gas includes, for example, argon, krypton, xenon, or the like as a rare gas, neon, helium, or the like as a buffer gas, and fluorine, chlorine, or the like as a halogen gas.

Further, an opening is formed in the container 10a. An electrically insulating plate 26 in which a feedthrough 25 is embedded is attached to the container 10a via an O-ring (not shown) so as to close the opening. The PPM 12 is arranged on the electrically insulating plate 26. The container 10a is grounded.

The PPM 12 includes a charging capacitor (not shown) and is connected to the main electrode 20 via the feedthrough 25. The PPM 12 includes a switch SW for causing discharge to occur at the main electrode 20. The charger 11 is connected to the charging capacitor of the PPM 12. Hereinafter, discharge occurring at the main electrode 20 is referred to as main discharge.

The main electrode 20 includes a cathode electrode 20a and an anode electrode 20b. The cathode electrode 20a and the anode electrode 20b are arranged in the container 10a so that discharge surfaces of the both face each other. The space between the discharge surface of the cathode electrode 20a and the discharge surface of the anode electrode 20b is referred to as a discharge space 27. Each of the cathode electrode 20a and the anode electrode 20b extends in the Z direction.

The cathode electrode 20a is supported by the electrically insulating plate 26 on a surface opposite to the discharge surface thereof, and is connected to the feedthrough 25. That is, the cathode electrode 20a is arranged at a position closer to the inner wall of the container 10a than the anode electrode 20b while facing the anode electrode 20b. The anode electrode 20b is supported by the ground plate 21 on a surface opposite to the discharge surface thereof. The anode electrode 20b is an example of the “first electrode” according to the technology of the present disclosure. The cathode electrode 20a is an example of the “second electrode” according to the technology of the present disclosure.

The ground plate 21 is connected to the container 10a via the wirings 22. The container 10a is grounded. Therefore, the ground plate 21 is grounded via the wirings 22. An end part of the ground plate 21 in the Z direction is fixed to the container 10a.

The fan 23 is a cross flow fan for circulating the laser gas in the container 10a, and is arranged on the opposite side of the discharge space 27 with respect to the ground plate 21. A motor 23a for rotationally driving the fan 23 is connected to the container 10a.

The laser gas blown out from the fan 23 flows into the discharge space 27. The flow direction of the laser gas flowing into the discharge space 27 is substantially parallel to the X direction. The laser gas flowing out from the discharge space 27 is sucked into the fan 23 via the heat exchanger 24. The heat exchanger 24 changes the temperature of the laser gas by performing heat exchange between a refrigerant supplied to the inside of the heat exchanger 24 and the laser gas.

The insulating guide 28 is arranged on a surface of the electrically insulating plate 26 facing the discharge space 27 so as to sandwich the cathode electrode 20a. The insulating guide 28 is formed in a shape to guide the flow of the laser gas so that the laser gas from the fan 23 efficiently flows between the cathode electrode 20a and the anode electrode 20b. The insulating guide 28 and the electrically insulating plate 26 are made of, for example, ceramics such as alumina (Al₂O₃) having low reactivity with a fluorine gas.

The conductive guide 29 is arranged on a surface of the ground plate 21 facing the discharge space 27 so as to sandwich the anode electrode 20b. Similarly to the insulating guide 28, the conductive guide 29 is formed in a shape to guide the flow of the laser gas so that the laser gas from the fan 23 efficiently flows between the cathode electrode 20a and the anode electrode 20b. The conductive guide 29 is made of, for example, a porous nickel metal having low reactivity with the fluorine gas.

A laser gas supply device 18a and a laser gas exhaust device 18b are connected to the laser chamber 10. The laser gas supply device 18a includes a valve and a flow rate control valve, and is connected to a gas cylinder accommodating the laser gas. The laser gas exhaust device 18b includes a valve and an exhaust pump.

At end parts of the container 10a, windows 19a, 19b for outputting light generated in the container 10a to the outside are provided, respectively. The laser chamber 10 is arranged such that the optical path of the optical resonator passes through the discharge space 27 and the windows 19a, 19b.

The line narrowing module 15 includes a prism 15a and a grating 15b. The prism 15a transmits the light output from the laser chamber 10 through the window 19a toward the grating 15b while expanding the beam width of the light.

The grating 15b is arranged in the Littrow arrangement so that the incident angle and the diffraction angle are the same. The grating 15b is a wavelength selection element that selectively extracts light having a wavelength near a particular wavelength in accordance with the diffraction angle. The spectral width of the light returning from the grating 15b to the laser chamber 10 via the prism 15a is line-narrowed.

The output coupling mirror 16 transmits a part of the light output from the laser chamber 10 through the window 19b, and reflects the other part back into the laser chamber 10. The surface of the output coupling mirror 16 is coated with a partial reflection film.

Light output from the laser chamber 10 reciprocates between the line narrowing module 15 and the output coupling mirror 16, and is amplified each time the light passes through the discharge space 27. A part of the amplified light is output as the pulse laser light PL via the output coupling mirror 16. The wavelength of the pulse laser light PL is in an ultraviolet range of 150 nm to 380 nm, and is, for example, an oscillation wavelength of an excimer laser device.

The pulse energy measurement unit 13 is arranged on the optical path of the pulse laser light PL output via the output coupling mirror 16. The pulse energy measurement unit 13 includes a beam splitter 13a, a light concentrating optical system 13b, and an optical sensor 13c.

The beam splitter 13a transmits the pulse laser light PL with a high transmittance and reflects a part of the pulse laser light PL toward the light concentrating optical system 13b. The light concentrating optical system 13b concentrates the light reflected by the beam splitter 13a on a light receiving surface of the optical sensor 13c. The optical sensor 13c measures the pulse energy of the light concentrated on the light receiving surface, and outputs the measurement value to the processor 14.

The pressure sensor 17 detects the gas pressure in the container 10a, and outputs the detection value to the processor 14. The processor 14 determines the gas pressure of the laser gas in the container 10a based on the detection value of the gas pressure and the charge voltage of the charger 11.

The charger 11 is a high voltage power source that supplies the charge voltage to the charging capacitor included in the PPM 12. The switch SW of the PPM 12 is controlled by the processor 14. When the switch SW is turned ON from OFF, the PPM 12 generates a high voltage pulse from the electric energy held in the charging capacitor and applies the high voltage pulse to the main electrode 20.

The processor 14 is a processing device that transmits and receives various signals to and from an exposure apparatus controller 110 provided in an exposure apparatus 100. For example, the exposure apparatus controller 110 transmits, to the processor 14, a target pulse energy of the pulse laser light PL to be output to the exposure apparatus 100, an oscillation trigger signal, and the like.

The processor 14 generally controls operation of each component of the gas laser device 2 based on various signals transmitted from the exposure apparatus controller 110, the measurement value of the pulse energy, the detection value of the gas pressure, and the like.

The processor 14 functions as a controller of the gas laser device 2. For example, the processor 14 is a processing device including a storage device in which a control program is stored and a central processing unit (CPU) that executes the control program. The processor 14 is specifically configured or programmed to perform various processes included in the present disclosure. The storage device is a non-transitory computer-readable storage medium, and includes, for example, a memory that is a main storage device and a storage that is an auxiliary storage device. Here, the storage device may be a semiconductor memory, a hard disk drive (HDD) device, a solid state drive (SSD) device, or a combination thereof.

Here, the gas laser device 2 is not necessarily limited to a line narrowing laser device, and may be a laser device that outputs natural oscillation light. For example, a high reflection mirror may be arranged in place of the line narrowing module 15.

### 1.2 Operation

Next, operation of the gas laser device 2 according to the comparative example will be described. First, the processor 14 controls the laser gas supply device 18a to supply the laser gas into the container 10a of the laser chamber 10, and drives the motor 23a to rotate the fan 23. As a result, as indicated by arrows in FIG. 2, the laser gas filled in the container 10a circulates.

The processor 14 receives the target pulse energy and the oscillation trigger signal transmitted from the exposure apparatus controller 110. Here, the oscillation trigger signal is a signal for instructing the gas laser device 2 to output one pulse of the pulse laser light PL.

The processor 14 sets the charge voltage corresponding to the target pulse energy in the charger 11. The processor 14 operates the switch SW of the PPM 12 in synchronization with the oscillation trigger signal.

When the switch SW of the PPM 12 is turned ON from OFF, a voltage is applied to each between the preionization inner electrode 33 and the preionization outer electrode 31 of the preionization electrode 30 and between the cathode electrode 20a and the anode electrode 20b. As a result, corona discharge occurs in the preionization electrode 30, and ultraviolet (UV) light is generated. When the laser gas in the discharge space 27 is irradiated with the UV light, the laser gas is preionized.

Thereafter, when the voltage between the cathode electrode 20a and the anode electrode 20b reaches a breakdown voltage, main discharge occurs in the discharge space 27. When the discharge direction of main discharge is defined as a direction in which electrons flow, the discharge direction is the direction from the cathode electrode 20a toward the anode electrode 20b. When main discharge occurs, the laser gas in the discharge space 27 is excited to emit light.

The light emitted from the laser gas is reflected by the line narrowing module 15 and the output coupling mirror 16 and reciprocates in the laser resonator, thereby performing laser oscillation. The light line-narrowed by the line narrowing module 15 is output from the output coupling mirror 16 as the pulse laser light PL.

A part of the pulse laser light PL output from the output coupling mirror 16 enters the pulse energy measurement unit 13. The pulse energy measurement unit 13 measures the pulse energy of the entering pulse laser light PL, and outputs the measurement value to the processor 14.

The processor 14 calculates a difference ΔE between the measurement value of the pulse energy and the target pulse energy. The processor 14 performs feedback control on the charge voltage based on the difference ΔE so that the measurement value of the pulse energy becomes the target pulse energy.

When the charge voltage is higher than a maximum value of an allowable range, the processor 14 controls the laser gas supply device 18a to supply the laser gas into the container 10a until a predetermined pressure is reached. Further, when the charge voltage is lower than a minimum value of the allowable range, the processor 14 controls the laser gas exhaust device 18b to exhaust the laser gas from the container 10a until a predetermined pressure is reached.

The pulse laser light PL transmitted through the pulse energy measurement unit 13 enters the exposure apparatus 100.

In the container 10a, discharge products are generated by main discharge in the discharge space 27. The generated discharge products are moved away from the discharge space 27 by the gas flow generated by the fan 23. Thus, discharge can be stabilized. Further, the temperature of the laser gas increases due to main discharge. The laser gas having the increased temperature is cooled by cooling water flowing in the heat exchanger 24 while passing through the heat exchanger 24.

### 1.3 Problem

When the repetition frequency of the pulse laser light PL output from the gas laser device 2 according to the comparative example is increased, the temperature of the laser gas is further increased, and therefore, the cooling capacity for the laser gas by the heat exchanger 24 needs to be increased. It is conceivable to enlarge the heat exchanger 24 to increase the cooling capacity for the laser gas. However, when the heat exchanger 24 is enlarged, the pressure loss of the laser gas by the heat exchanger 24 increases. When the pressure loss is increased, the flow rate of the laser gas in the discharge space 27 decreases, and therefore, it becomes difficult to perform high repetitive operation of the pulse laser light PL.

Therefore, an object of the present disclosure is to increase the cooling capacity for the laser gas without enlarging the pressure loss of the laser gas.

### 2. Embodiment

### 2.1 Configuration

The gas laser device 2 according to an embodiment of the present disclosure has a configuration similar to that of the gas laser device 2 according to the comparative example except that the configuration of the laser chamber 10 is different.

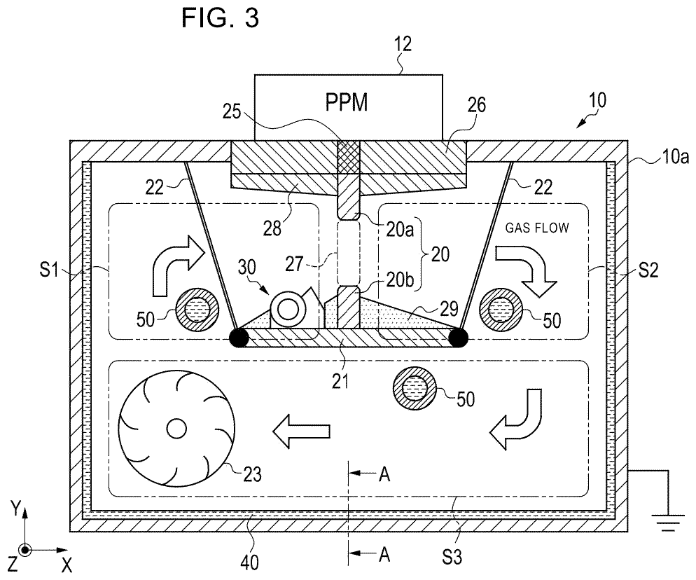

FIG. 3 shows in detail the configuration of the laser chamber 10 according to the embodiment. The laser chamber 10 of the present embodiment differs from that of the comparative embodiment only in that a plurality of heat pipes 40 and a plurality of heat exchangers 50 are provided in the container 10a. The plurality of heat exchangers 50 are provided in place of the heat exchanger 24 of the comparative example.

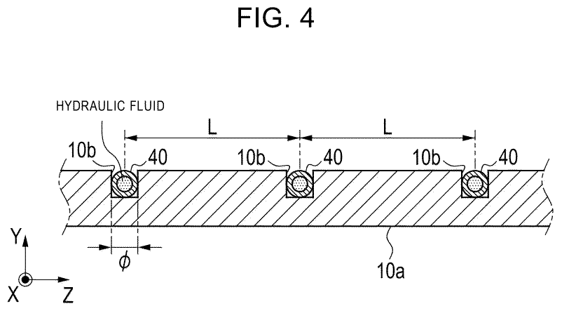

FIG. 4 shows a cross-section of the bottom of the container 10a taken along line A-A of FIG. 3 (i.e. a YZ plane). The plurality of heat pipes 40 are arranged on the inner wall of the container 10a. The plurality of heat pipes 40 are independent from each other and are separately arranged on the inner wall of the container 10a.

Specifically, the heat pipes 40 are fitted and fixed to grooves 10b formed on the inner wall of the container 10a. The heat pipes 40 are arranged parallel to an XY plane and extend over a bottom surface and a pair of side surfaces of the inner wall of the container 10a. The length of each heat pipe 40 is preferably in a range of 70% to 90% both inclusive of the circumferential length of the inner surface of the container 10a. The circumferential length of the inner surface of the container 10a means the length of the inner circumference when the container 10a is taken along the XY plane. The inner surface of the container 10a includes the bottom surface, the pair of side surfaces, and a top surface of the inner wall. Not limited to the bottom surface and the pair of side surfaces, at least a part of the heat pipes 40 may be arranged on the top surface.

Further, the heat pipes 40 are arranged at regular intervals in the Z direction. The interval L between two adjacent heat pipes 40 is in a range of 100 mm to 300 mm both inclusive.

The cross-sectional shape of each heat pipe 40 is, for example, a circle. An outer diameter φ of each heat pipe 40 is preferably in a range of 5 mm to 10 mm both inclusive. The cross-sectional shape of each heat pipe 40 may be a shape other than a circle having a surface area similar to that of a circular pipe having an outer diameter in the range of 5 mm to 10 mm both inclusive.

Further, the heat pipes 40 are formed of a material having high thermal conductivity such as copper (Cu), and hydraulic fluid having high volatility is enclosed therein. A capillary structure is formed on the inner surface of each heat pipe 40.

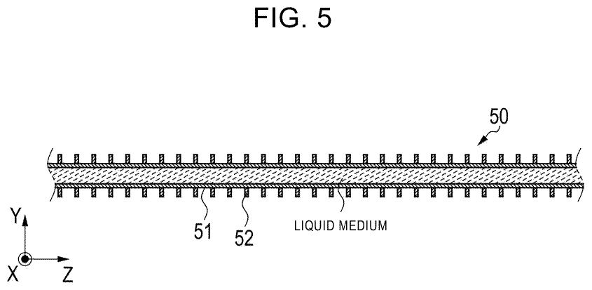

FIG. 5 shows the configuration of the heat exchanger 50. The heat exchanger 50 includes a pipe 51 and a plurality of fins 52 formed on the outer periphery of the pipe 51. A liquid medium such as cooling water flows inside the pipe 51. The heat exchanger 50 extends in the Z direction. The plurality of heat exchangers 50 are parallel to each other.

As shown in FIG. 3, the plurality of heat exchangers 50 are arranged so as to avoid a region where the flow rate of the laser gas is large in the container 10a. Specifically, the plurality of heat exchangers 50 are arranged in the container 10a so as to be spaced apart from each other in a region having a flow rate of the laser gas being 50% or less of the maximum flow rate thereof. In the present embodiment, the plurality of heat exchangers 50 are arranged in a first space S1, a second space S2, and a third space S3. The first space S1 is a region on the upstream side of the gas flow from the discharge space 27. The second space S2 is a region on the downstream side of the gas flow from the discharge space 27. The third space S3 is a region opposite to the discharge space 27 with respect to the anode electrode 20b. The laser gas blown out from the fan 23 flows through the first space S1, the second space S2, and the third space S3 in the order thereof. The fan 23 is arranged in the third space S3.

Each heat exchanger 50 may be arranged in any region in the container 10a as long as the region has a flow rate of the laser gas being 50% or less of the maximum flow rate thereof. The number of the heat exchangers 50 may be two or more, and is not specifically limited. In the present embodiment, one heat exchanger 50 is arranged in each of the first space S1, the second space S2, and the third space S3, but two or more heat exchangers 50 may be arranged in each space.

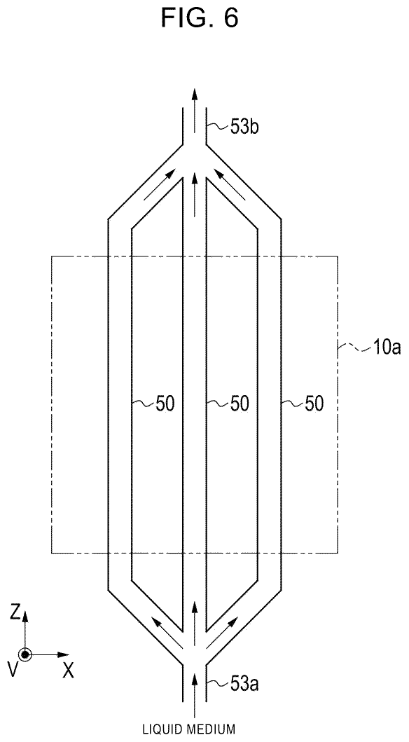

FIG. 6 shows an example of a connection state of the plurality of heat exchangers 50. The ends of the plurality of heat exchangers 50 are connected in common. Specifically, one end of each of the heat exchangers 50 is connected to the pipe 53a, and the other end thereof is connected to the pipe 53b. The liquid medium flows into each of the heat exchangers 50 from the pipe 53a, and the liquid medium flowing out from the respective heat exchangers 50 flows into the pipe 53b. In the present embodiment, the plurality of heat exchangers 50 are connected to the pipes 53a, 53b outside the container 10a, but may be connected to the pipes 53a, 53b inside the container 10a.

For example, the cooling capacity of the plurality of heat exchangers 50 is preferably in a range of 10 kW to 15 kW both inclusive in total.

### 2.2 Operation

Operation of the gas laser device 2 according to the present embodiment is similar to that of the comparative example except that the effect caused by provision of the plurality of heat pipes 40 and the plurality of the heat exchangers 50 in the container 10a is different.

In the present embodiment, in the high-temperature region of the laser gas in the container 10a, the hydraulic fluid in the heat pipes 40 evaporates, and thus the latent heat is absorbed. The latent heat absorption thus cools the high-temperature region. On the other hand, in the low-temperature region of the laser gas in the container 10a, the latent heat is released by condensation of the hydraulic fluid. The latent heat release thus heats the low-temperature region. The condensed hydraulic fluid returns to liquid and moves to the high-temperature region by capillary phenomenon in the heat pipes 40. As a result of the repeated occurrence of such phenomena, the laser gas in the container 10a is uniformized in temperature. The heat of the laser gas with the temperature uniformized is exhausted by the plurality of heat exchangers 50.

### 2.3 Effect

When the plurality of heat pipes 40 are not provided in the container 10a as in the comparative example, the temperature of the laser gas in the container 10a becomes nonuniform, for example, as being higher in the downstream-side region from the discharge space 27 than in other regions. Therefore, to increase the cooling efficiency of the laser gas, it is necessary to arrange the heat exchanger 50 in a region where the temperature is high, or to arrange a large heat exchanger 50.

On the other hand, in the present embodiment, since the plurality of heat pipes 40 are arranged on the inner wall of the container 10a, the temperature of the laser gas becomes uniform by the above-described effect. Accordingly, since the same cooling efficiency can be obtained even when the heat exchangers 50 are arranged anywhere in the container 10a, it is possible to arrange the heat exchangers 50 to avoid the regions where the flow rate of the laser gas is large so as not to increase the pressure loss. Further, by arranging the plurality of heat exchangers 50 while avoiding the region where the flow rate of the laser gas is large, the cooling capacity is increased.

Therefore, according to the present embodiment, when the repetition frequency of the pulse laser light PL output from the gas laser device 2 is increased, it is possible to increase the cooling capacity of the laser gas without increasing the pressure loss of the laser gas. In particular, by arranging the plurality of heat exchangers 50 in the container 10a in the region having a flow rate of the laser gas being 50% or less of the maximum flow rate thereof, it is possible to suppress the pressure loss efficiently while increasing the cooling capacity of the laser gas, as compared with the case of arranging in a region having a large flow rate.

Further, when the laser gas in the container 10a is not uniform in temperature, thermal distortion occurs in the container 10a. This causes vibration generated in the fan 23, breakage of a brittle material component, and the like. According to the present embodiment, since the plurality of heat pipes 40 uniformize the temperature of the laser gas in the container 10a, thermal distortion of the container 10a can be suppressed.

### 3. Electronic Device Manufacturing Method

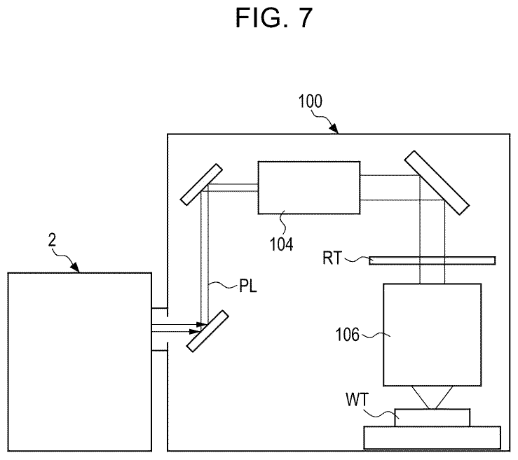

FIG. 7 schematically shows a configuration example of the exposure apparatus 100. The exposure apparatus 100 includes an illumination optical system 104 and a projection optical system 106. For example, the illumination optical system 104 illuminates a reticle pattern of a reticle (not shown) arranged on a reticle stage RT with the pulse laser light PL incident from the gas laser device 2. The projection optical system 106 causes the pulse laser light PL transmitted through the reticle to be imaged as being reduced and projected on a workpiece (not shown) arranged on a workpiece table WT. The workpiece is a photosensitive substrate such as a semiconductor wafer on which photoresist is applied.

The exposure apparatus 100 synchronously translates the reticle stage RT and the workpiece table WT to expose the workpiece to the pulse laser light PL reflecting the reticle pattern. After the reticle pattern is transferred onto the semiconductor wafer by the exposure process described above, a semiconductor device can be manufactured through a plurality of processes. The semiconductor device is an example of the “electronic device” in the present disclosure.

Here, not limited to the manufacturing of an electronic device, the gas laser device 2 may be used for laser processing such as drilling.

The description above is intended to be illustrative and the present disclosure is not limited thereto. Therefore, it would be obvious to those skilled in the art that various modifications to the embodiment of the present disclosure would be possible without departing from the spirit and the scope of the appended claims.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of the any thereof and any other than A, B, and C.

What is claimed is:

1. A laser chamber of a gas laser device configured to output laser light, the laser chamber comprising:
a container filled with a laser gas;
a first electrode extending in a first direction and arranged in the container;
a second electrode arranged at a position closer to an inner wall of the container than the first electrode while extending in the first direction and facing the first electrode in a second direction perpendicular to the first direction;
a fan configured to cause the laser gas to flow through a discharge space between the first electrode and the second electrode;
a plurality of heat pipes arranged on the inner wall of the container; and
a plurality of heat exchangers arranged as being spaced apart from each other in the container.

2. The laser chamber according to claim 1,
wherein the heat pipes are arranged parallel to a plane perpendicular to the first direction.

3. The laser chamber according to claim 2,
wherein the heat pipes are arranged at intervals in the first direction, each interval being in a range of 100 mm to 300 mm both inclusive.

4. The laser chamber according to claim 2,
wherein a length of each of the heat pipes is in a range of 70% to 90% both inclusive of a circumferential length of an inner surface of the container.

5. The laser chamber according to claim 1,
wherein each of the heat pipes has a circular cross-sectional shape having an outer diameter in a range of 5 mm to 10 mm both inclusive.

6. The laser chamber according to claim 1,
wherein each of the heat pipes has a capillary structure formed on an inner surface thereof, and hydraulic fluid is enclosed therein.

7. The laser chamber according to claim 1,
wherein each of the heat pipes is fitted and fixed to grooves formed on the inner wall of the container.

8. The laser chamber according to claim 1,
wherein the heat exchangers are arranged in the container in a region having a flow rate of the laser gas being 50% or less of a maximum flow rate thereof.

9. The laser chamber according to claim 1,
wherein the heat exchangers are arranged in a first space on an upstream side from the discharge space, a second space on a downstream side from the discharge space, and a third space on a side opposite to the discharge space with respect to the first electrode.

10. The laser chamber according to claim 1,
wherein a total cooling capacity of the heat exchangers is in a range of 10 kW to 15 kW both inclusive.

11. The laser chamber according to claim 1,
wherein each of the heat exchangers includes a pipe and a plurality of fins formed on an outer periphery of the pipe.

12. The laser chamber according to claim 11,
wherein the pipe extends in the first direction.

13. The laser chamber according to claim 1,
wherein ends of the heat exchangers are connected in common inside or outside the container.

14. A gas laser device configured to output laser light and comprising an optical resonator and a laser chamber arranged to have an optical path of the optical resonator pass therethrough,
the laser chamber including:
a container filled with a laser gas;
a first electrode extending in a first direction and arranged in the container;
a second electrode arranged at a position closer to an inner wall of the container than the first electrode while extending in the first direction and facing the first electrode in a second direction perpendicular to the first direction;
a fan configured to cause the laser gas to flow through a discharge space between the first electrode and the second electrode;
a plurality of heat pipes arranged on the inner wall of the container; and
a plurality of heat exchangers arranged as being spaced apart from each other in the container.

15. An electronic device manufacturing method comprising:
generating laser light using a gas laser device;
outputting the laser light to an exposure apparatus; and
exposing a photosensitive substrate to the laser light in the exposure apparatus to manufacture an electronic device,
the gas laser device being configured to output the laser light and including an optical resonator and a laser chamber arranged to have an optical path of the optical resonator pass therethrough, and
the laser chamber including:
a container filled with a laser gas;
a first electrode extending in a first direction and arranged in the container;
a second electrode arranged at a position closer to an inner wall of the container than the first electrode while extending in the first direction and facing the first electrode in a second direction perpendicular to the first direction;
a fan configured to cause the laser gas to flow through a discharge space between the first electrode and the second electrode;
a plurality of heat pipes arranged on the inner wall of the container; and
a plurality of heat exchangers arranged as being spaced apart from each other in the container.
